(19) United States
(12) Patent Application Publication
(10) Pub. No.: US 2024/0431208 A1
(43) Pub. Date: Dec. 26, 2024

(54) HIGH-TEMPERATURE POLARIZATION METHOD FOR STRIP-SHAPED OR ROD-SHAPED PIEZOELECTRIC CERAMICS

(71) Applicant: GUILIN UNIVERSITY OF ELECTRONIC TECHNOLOGY, Guilin (CN)

(72) Inventors: YAN WANG, Guilin (CN); HAOTIAN XU, Guilin (CN); YI LUO, Guilin (CN); YINGHONG ZHANG, Guilin (CN); JINLONG CHEN, Guilin (CN); CHENG GAO, Guilin (CN); CHOU MO, Guilin (CN); SHIQI LIU, Guilin (CN)

(21) Appl. No.: 18/824,224

(22) Filed: Sep. 4, 2024

Related U.S. Application Data
(63) Continuation of application No. PCT/CN2023/111934, filed on Aug. 9, 2023.

(30) Foreign Application Priority Data
Aug. 12, 2022 (CN) 202210968739.6

(51) Int. Cl. H10N 30/045

(52) U.S. Cl. CPC H10N 30/045

(57) ABSTRACT

The present disclosure relates to the technical field of piezoelectric ceramics polarization, and particularly relates to a high-temperature polarization method for strip-shaped or rod-shaped piezoelectric ceramics. The piezoelectric ceramics are heated to a temperature above a Curie temperature point in a closed polarization environment, and an electric domain turning resistance of the piezoelectric ceramics is reduced to a preset value. Voltages are applied to two ends of the piezoelectric ceramics, and an electric domain orientation of the piezoelectric ceramics are converted, through a temperature reduction and pressure increase method, to be consistent with a direction in which an electric field is applied. The piezoelectric ceramics are cooled to a room temperature, and polarization is completed. According to the method, voltages applied to two ends of a piezoelectric fiber can be reduced by reducing internal resistance of the piezoelectric fiber.

### CROSS-REFERENCE TO RELATED APPLICATIONS

This application is a continuation of co-pending International Patent Application No. PCT/CN2023/111934, filed on Aug. 9, 2023, which claims the priority and benefit of Chinese patent application number 202210968739.6, filed on Aug. 12, 2022 with China National Intellectual Property Administration, the entire contents of which are incorporated herein by reference.

### TECHNICAL FIELD

The present disclosure relates to the field of a piezoelectric ceramics polarization technology, and particularly relates to a high-temperature polarization method for strip-shaped or rod-shaped piezoelectric ceramics.

### BACKGROUND

Piezoelectric materials are polarized such that piezoelectric ceramics can obtain piezoelectricity. The piezoelectric ceramics are formed by randomly embedding small grains. Several small regions appear in the grains. Spontaneous polarization of unit cells in each small region has the same direction, and this small region is referred to as an electric domain. Spontaneous polarization directions between adjacent electric domains are different and electrically neutral. Polarization is to apply an electric field to the piezoelectric ceramics. An electric domain is turned under the conditions of set temperature and time parameters, regularity is formed, and then piezoelectricity is shown.

A traditional polarization technology uses low-temperature oil bath polarization, but it is required to apply a strong polarization voltage to the piezoelectric ceramics, such that the polarization voltage exceeds a breakdown electric field of materials of the piezoelectric ceramics. Therefore, materials are destructed, and resources are wasted.

### SUMMARY

An objective of the present disclosure is to provide a high-temperature polarization method for strip-shaped or rod-shaped piezoelectric ceramics, which aims to solve the problem that in a traditional low-temperature polarization process of the piezoelectric ceramics, an excessive polarization voltage is likely to break down an electric field damage material, and resources are wasted is solved.

In order to realize the above objective, the present disclosure provides a high-temperature polarization method for strip-shaped or rod-shaped piezoelectric ceramics. The method includes steps as follows:
heating the piezoelectric ceramics to a temperature above a Curie temperature point in a closed polarization environment, and reducing an electric domain turning resistance of the piezoelectric ceramics to a preset value;
applying voltages to two ends of the piezoelectric ceramics, and converting, through a temperature reduction and pressure increase method, an electric domain orientation of the piezoelectric ceramics to be consistent with a direction in which an electric field is applied; and
cooling the piezoelectric ceramics to a room temperature, and completing polarization.

The temperature reduction and pressure increase method includes a natural cooling pressurization method and a temperature control pressurization method.

The converting, through a natural cooling pressurization method, an electric domain orientation of the piezoelectric ceramics to be consistent with a direction in which an electric field is applied specifically includes:
converting and segmenting the electric domain orientation of the piezoelectric ceramics, obtaining a conversion stage, and dividing the conversion stage into several conversion sub-stages;
applying conversion voltages of first set duration to two ends of the piezoelectric ceramics, reducing a temperature of the piezoelectric ceramics at a preset amplitude, completing a conversion sub-stage in the conversion sub-stages; and
completing a conversion sub-stage of a previous cycle, increasing a voltage of the conversion voltage, and carrying out a conversion sub-stage of a next cycle until all the conversion sub-stages are completed.

The first set duration is less than duration of the conversion sub-stages.

The conversion voltage is a constant voltage. A conversion voltage of a current conversion sub-stage is higher than a conversion voltage of a previous cycle of conversion sub-stage by a set voltage.

The converting, through a temperature control pressurization method, an electric domain orientation of the piezoelectric ceramics to be consistent with a direction in which an electric field is applied specifically includes:
setting a set number of conversion temperature points in temperature descending order;
applying a constant voltage for second set duration at a current conversion temperature point, and carrying out constant voltage conversion on the electric domain orientation of the piezoelectric ceramics; and
completing conversion of a previous cycle, increasing a voltage amplitude of the constant voltage, and carrying out constant voltage conversion at a conversion temperature point of a next cycle until constant voltage conversion at all conversion temperature points is completed.

The second set duration is consistent with duration of the constant voltage conversion.

The heating the piezoelectric ceramics to a temperature above the Curie temperature point in a closed polarization environment specifically includes:
placing the piezoelectric ceramics in a closed polarization environment, and heating the polarization environment; and
taking a gas as a medium in the polarization environment, and heating the piezoelectric ceramics through a heat conduction method until the piezoelectric ceramics reach a temperature above the Curie temperature point.

According to a high-temperature polarization method for strip-shaped or rod-shaped piezoelectric ceramics in the present disclosure, the piezoelectric ceramics are heated to a temperature above a Curie temperature point in a closed polarization environment, and an electric domain turning resistance of the piezoelectric ceramics is reduced to a preset value. Voltages are applied to two ends of the piezoelectric ceramics, and an electric domain orientation of the piezoelectric ceramics are converted, through a temperature reduction and pressure increase method, to be consistent with a direction in which an electric field is applied. The piezoelectric ceramics are cooled to a room temperature, and polarization is completed. According to the method, voltages applied to two ends of a piezoelectric fiber can be reduced by reducing internal resistance of the piezoelectric fiber. In order to prevent a depolarization phenomenon of the piezoelectric fiber caused by an overhigh temperature, polarization is completed through the temperature reduction and pressure increase method above the Curie temperature point of the piezoelectric fiber. The problem that in a traditional low-temperature polarization process of the piezoelectric ceramics, an excessive polarization voltage is likely to break down an electric field damage material, and resource waste is caused is solved.

### BRIEF DESCRIPTION OF DRAWINGS

In order to more clearly describe the technical solution in examples of the present disclosure or in the prior art, accompanying drawings required to be used in descriptions of the examples or the prior art will be briefly introduced. Obviously, accompanying drawings in the following descriptions are merely some examples of the present disclosure. Those of ordinary skill in the art would also derive other accompanying drawings from these accompanying drawings without making inventive efforts.

FIG. 1 is a flow diagram of a high-temperature polarization method for strip-shaped or rod-shaped piezoelectric ceramics according to the prevent disclosure.

FIG. 2 is a flow diagram of a specific method of converting, through a natural cooling pressurization method, an electric domain orientation of piezoelectric ceramics to be consistent with a direction in which an electric field is applied.

FIG. 3 is a flow diagram of a specific method of converting, through a temperature control pressurization method, an electric domain orientation of piezoelectric ceramics to be consistent with a direction in which an electric field is applied.

FIG. 4 is a schematic structural diagram of a polarization device according to the present disclosure.

1—polarization box, 2—electrode, 3—control display screen, 4—control knob, 5—piezoelectric fiber and 6—fixture table.

### DETAILED DESCRIPTION OF THE EMBODIMENTS

Examples of the present disclosure will be described in detail below. Instances of the examples are shown in accompanying drawings, throughout which identical or similar reference numerals denote identical or similar elements or elements having identical or similar functions. The following examples described with reference to the accompanying drawings are exemplary and merely used to explain the present disclosure, but cannot be construed as limitations on the present disclosure.

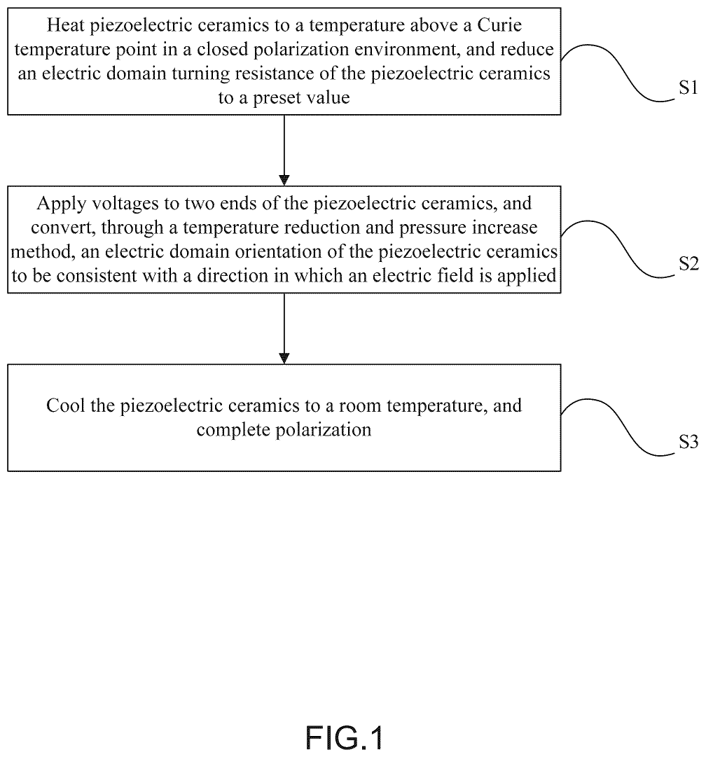

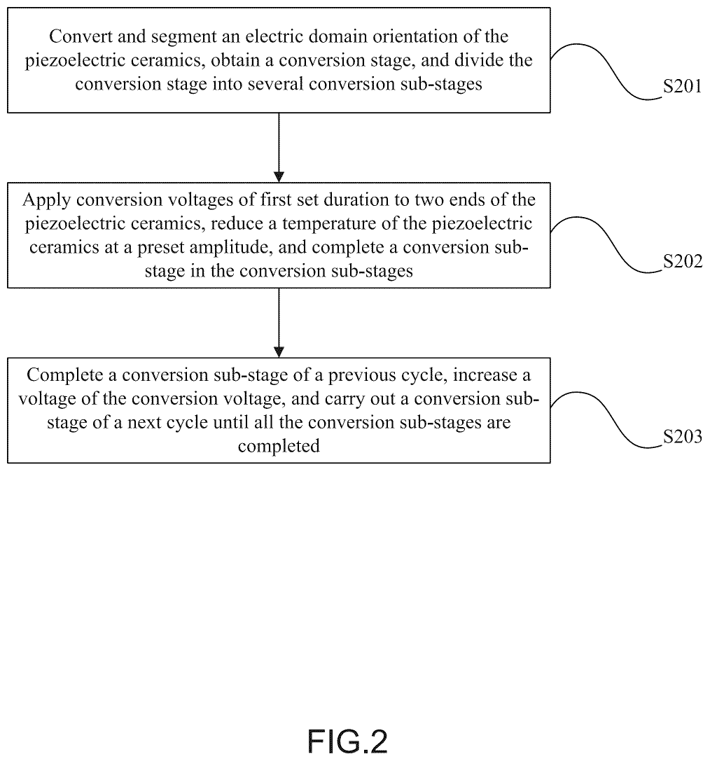

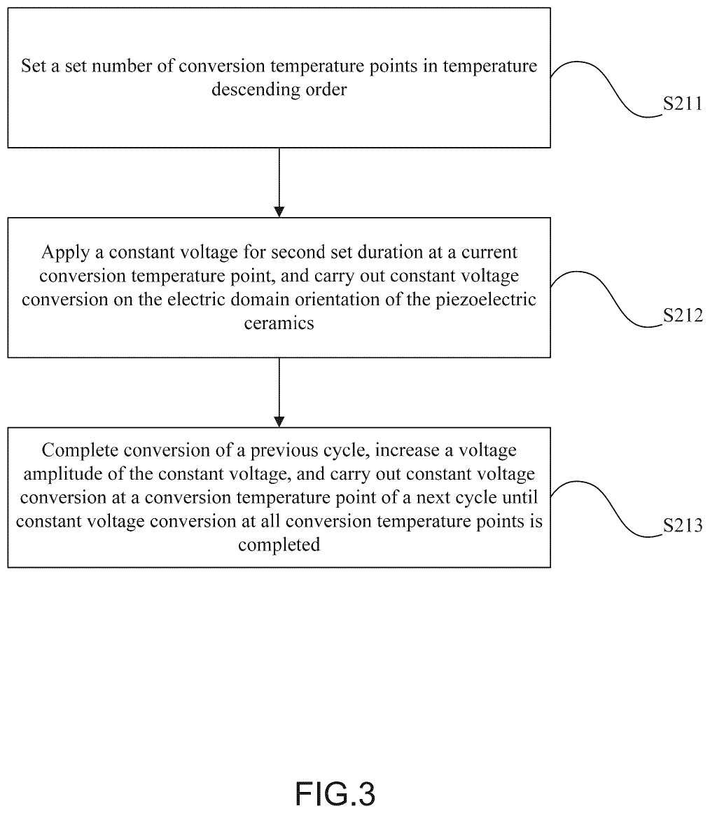

With reference to FIG. 1-FIG. 3, the present disclosure provides a high-temperature polarization method for strip-shaped or rod-shaped piezoelectric ceramics. The method includes steps as follows:

S1: Heat the piezoelectric ceramics to a temperature above a Curie temperature point in a closed polarization environment, and reduce an electric domain turning resistance of the piezoelectric ceramics to a preset value.

The step of heating the piezoelectric ceramics to a temperature above the Curie temperature point in a closed polarization environment specifically includes:

S11: Place the piezoelectric ceramics in a closed polarization environment, and heat the polarization environment.

S12: Take a gas as a medium in the polarization environment, and heat the piezoelectric ceramics through a heat conduction method until the piezoelectric ceramics reach a temperature above the Curie temperature point.

S2: Apply voltages to two ends of the piezoelectric ceramics, and convert, through a temperature reduction and pressure increase method, an electric domain orientation of the piezoelectric ceramics to be consistent with a direction in which an electric field is applied.

Specifically, the temperature reduction and pressure increase method includes a natural cooling pressurization method and a temperature control pressurization method.

The step of converting, through a natural cooling pressurization method, an electric domain orientation of the piezoelectric ceramics to be consistent with a direction in which an electric field is applied specifically includes:

S201: Convert and segment the electric domain orientation of the piezoelectric ceramics, obtain a conversion stage, and divide the conversion stage into several conversion sub-stages.

S202: Apply conversion voltages of first set duration to two ends of the piezoelectric ceramics, reduce a temperature of the piezoelectric ceramics at a preset amplitude, and complete a conversion sub-stage in the conversion sub-stages.

Specifically, the first set duration is less than duration of the conversion sub-stages. The conversion voltage is a constant voltage. A conversion voltage of a current conversion sub-stage is higher than a conversion voltage of a previous cycle of conversion sub-stage by a set voltage.

S203: Complete a conversion sub-stage of a previous cycle, increase a voltage of the conversion voltage, and carry out a conversion sub-stage of a next cycle until all the conversion sub-stages are completed.

The step of converting, through a temperature control pressurization method, an electric domain orientation of the piezoelectric ceramics to be consistent with a direction in which an electric field is applied specifically includes:

S211: Set a set number of conversion temperature points in temperature descending order.

S212: Apply a constant voltage for second set duration at a current conversion temperature point, and carry out constant voltage conversion on the electric domain orientation of the piezoelectric ceramics.

Specifically, the second set duration is consistent with duration of the constant voltage conversion.

S213: Complete conversion of a previous cycle, increase a voltage amplitude of the constant voltage, and carry out constant voltage conversion at a conversion temperature point of a next cycle until constant voltage conversion at all conversion temperature points is completed.

S3: Cool the piezoelectric ceramics to a room temperature, and complete polarization.

In order to better understand the present disclosure, the content of the present disclosure will be further described below in combination with accompanying drawings of the description and instances.

### Example 1

The example provides a high-temperature polarization method for strip-shaped or rod-shaped piezoelectric ceramics. A schematic diagram of the polarization method is as shown in FIG. 1 and specifically includes:

S1: Heat a piezoelectric fiber to a temperature above a Curie temperature point in a closed polarization environment, and reduce an electric domain turning resistance of the piezoelectric fiber to a preset value.

The piezoelectric fiber has a diameter of 0.15 mm-0.3 mm and a length of 20 mm-120 mm. The Curie temperature point is 335° C. The piezoelectric fiber is in a paraelectric phase above the Curie temperature point, and the piezoelectric fiber is in a ferroelectric phase below the Curie temperature point. The paraelectric phase causes the piezoelectric fiber to generate depolarization. Thus, the temperature should be controlled within 10° C.-50° C. above the Curie temperature point, and is set as 360° C. in Example 1.

S2: Apply voltages to two ends of the piezoelectric fiber, and convert, through a temperature reduction and pressure increase method, an electric domain orientation of the piezoelectric fiber to be consistent with a direction in which an electric field is applied.

A specific method includes:

S201: Convert and segment the electric domain orientation of the piezoelectric ceramics, obtain a conversion stage, and divide the conversion stage into several conversion sub-stages.

Specifically, a conversion stage of an electric domain orientation is divided into 5 conversion sub-stages.

S202: Apply conversion voltages of first set duration to two ends of the piezoelectric ceramics, reduce a temperature of the piezoelectric ceramics at a preset amplitude, complete a conversion sub-stage in the conversion sub-stages.

Specifically, the first set duration is 5 min, the conversion voltage is 1000 V, and the preset amplitude is 60° C.

S203: Complete a conversion sub-stage of a previous cycle, increase a voltage of the conversion voltage, and carry out a conversion sub-stage of a next cycle until all the conversion sub-stages are completed.

Specifically, an increase amplitude of a voltage is 500 V.

A specific method includes:

S211: Set a set number of conversion temperature points in temperature descending order.

Specifically, 6 conversion temperature points are provided, and are 380° C., 330° C., 280° C., 230° C., 180° C. and 130° C. respectively.

S212: Apply a constant voltage for second set duration at a current conversion temperature point, and carry out constant voltage conversion on the electric domain orientation of the piezoelectric ceramics.

Specifically, the second set duration is 5 min, and the constant voltage is 1200 V.

S213: Complete conversion of a previous cycle, increase a voltage amplitude of the constant voltage, and carry out constant voltage conversion at a conversion temperature point of a next cycle until constant voltage conversion at all conversion temperature points is completed.

Specifically, the voltage amplitude is 300 V.

S3: Cool the piezoelectric fiber to room temperature 25° C., and complete polarization.

### Example 2

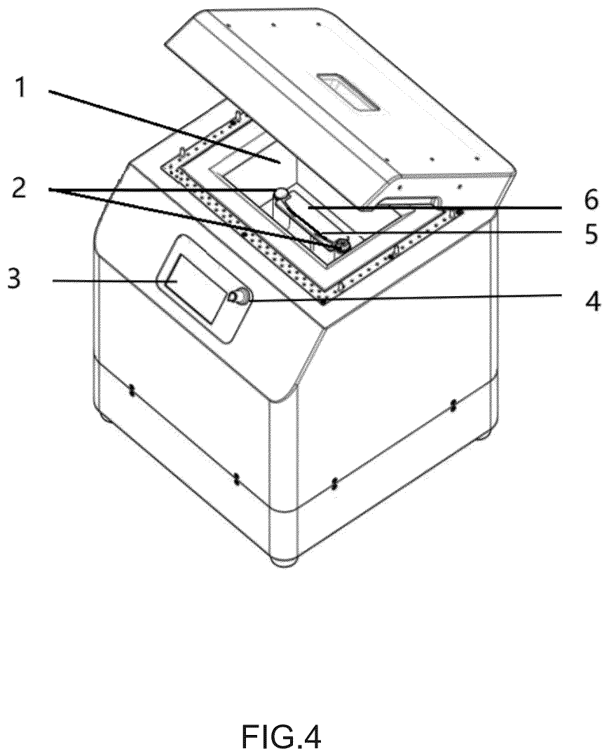

With reference to FIG. 4, on the basis of the polarization method provided in Example 1, a piezoelectric fiber polarization device based on the polarization method is provided in the example. The polarization device includes a polarization box 1, two electrodes 2, a control display screen 3, a control knob 4, a piezoelectric fiber 5 and a fixture table 6.

The two electrodes 2 are both arranged in the polarization box 1. The fixture table 6 is arranged between the two electrodes 2. The control display screen 3 is fixedly connected to the polarization box 1 and is located on the outer side of the polarization box 1. The control knob 4 is arranged on the side of the control display screen 3 away from the polarization box 1. The piezoelectric fiber 5 is arranged between the two electrodes 2.

In the embodiment, the polarization box 1 is an experimental environment for polarization. A temperature of the polarization box 1 is equal to a polarization temperature. The two electrodes 2 are used for being connected to two ends of the piezoelectric fiber 5 and conduct an electric current. The control display screen 3 is used for displaying changes of parameters such as a polarization temperature, a polarization voltage and polarization time during a polarization experiment. The control knob 4 is used for changing a polarization method, the polarization temperature, the polarization voltage, the polarization time and segment number settings. The piezoelectric fiber 5 is a polarization initial material. The fixture table 6 is connected to the two electrodes 2 and is used for supporting the piezoelectric fiber 5.

The above disclosure is only a preferred example of the patent name of the present disclosure, and certainly cannot limit the range of right of the present disclosure. Those skilled in the art can understand that all or part of the processes for implementing the above examples, and equivalent changes made according to the claims of the present disclosure still fall within the scope covered by the present disclosure.

What is claimed is:

1. A high-temperature polarization method for strip-shaped or rod-shaped piezoelectric ceramics, comprising steps as follows:
heating the piezoelectric ceramics to a temperature above a Curie temperature point in a closed polarization environment, and reducing an electric domain turning resistance of the piezoelectric ceramics to a preset value;
applying voltages to two ends of the piezoelectric ceramics, and converting, through a temperature reduction and pressure increase method, an electric domain orientation of the piezoelectric ceramics to be consistent with a direction in which an electric field is applied; and
cooling the piezoelectric ceramics to a room temperature, and completing polarization.

2. The high-temperature polarization method for strip-shaped or rod-shaped piezoelectric ceramics according to claim 1, wherein
the temperature reduction and pressure increase method comprises a natural cooling pressurization method and a temperature control pressurization method.

3. The high-temperature polarization method for strip-shaped or rod-shaped piezoelectric ceramics according to claim 2, wherein
the converting, through a natural cooling pressurization method, an electric domain orientation of the piezoelectric ceramics to be consistent with a direction in which an electric field is applied specifically comprises:
converting and segmenting the electric domain orientation of the piezoelectric ceramics, obtaining a conversion stage, and dividing the conversion stage into several conversion sub-stages;
applying conversion voltages of first set duration to two ends of the piezoelectric ceramics, reducing a temperature of the piezoelectric ceramics at a preset amplitude, completing a conversion sub-stage in the conversion sub-stages; and
completing a conversion sub-stage of a previous cycle, increasing a voltage of the conversion voltage, and carrying out a conversion sub-stage of a next cycle until all the conversion sub-stages are completed.

4. The high-temperature polarization method for strip-shaped or rod-shaped piezoelectric ceramics according to claim 3, wherein
the first set duration is less than duration of the conversion sub-stages.

5. The high-temperature polarization method for strip-shaped or rod-shaped piezoelectric ceramics according to claim 3, wherein
the conversion voltage is a constant voltage, and a conversion voltage of a current conversion sub-stage is higher than a conversion voltage of a previous cycle of conversion sub-stage by a set voltage.

6. The high-temperature polarization method for strip-shaped or rod-shaped piezoelectric ceramics according to claim 2, wherein
the converting, through a temperature control pressurization method, an electric domain orientation of the piezoelectric ceramics to be consistent with a direction in which an electric field is applied specifically comprises:
setting a set number of conversion temperature points in temperature descending order;
applying a constant voltage for second set duration at a current conversion temperature point, and carrying out constant voltage conversion on the electric domain orientation of the piezoelectric ceramics; and
completing conversion of a previous cycle, increasing a voltage amplitude of the constant voltage, and carrying out constant voltage conversion at a conversion temperature point of a next cycle until constant voltage conversion at all conversion temperature points is completed.

7. The high-temperature polarization method for strip-shaped or rod-shaped piezoelectric ceramics according to claim 6, wherein
the second set duration is consistent with duration of the constant voltage conversion.

8. The high-temperature polarization method for strip-shaped or rod-shaped piezoelectric ceramics according to claim 1, wherein
the heating the piezoelectric ceramics to a temperature above the Curie temperature point in a closed polarization environment specifically comprises:
placing the piezoelectric ceramics in a closed polarization environment, and heating the polarization environment; and
taking a gas as a medium in the polarization environment, and heating the piezoelectric ceramics through a heat conduction method until the piezoelectric ceramics reach a temperature above the Curie temperature point.
